(19) United States
(12) Patent Application Publication
(10) Pub. No.: US 2021/0166777 A1
(43) Pub. Date: Jun. 3, 2021

(54) MEMORY REPAIR CIRCUIT, MEMORY REPAIR METHOD, AND MEMORY MODULE USING MEMORY REPAIR CIRCUIT

(71) Applicant: iSTART-Tek Technologies Co.,Ltd, HSINCHU COUNTY (TW)

(72) Inventor: YUNG-SHENG SHEN, HSINCHU COUNTY (TW)

(21) Appl. No.: 16/901,713

(22) Filed: Jun. 15, 2020

(30) Foreign Application Priority Data
Dec. 3, 2019 (TW) 108144076

(51) Int. Cl. G11C 29/44; G11C 29/38; G11C 29/00

(52) U.S. Cl. CPC G11C 29/4401; G11C 29/886; G11C 29/38

(57) ABSTRACT

A memory repair circuit, a memory repair method and a memory module using the memory repair circuit are disclosed. The memory repair circuit includes a non-volatile storage unit, a volatile storage unit, a controller, a self-test circuit, and a repair information generating circuit. The non-volatile storage unit stores a first repair information. The volatile storage unit functions as a data transmission bridge between the non-volatile storage unit and the repair information generating circuit. The controller controls reading and burning of the first repair information and a second repair information. The self-test circuit performs a built-in self-test on a main memory configured according to the first repair information. The repair information generating circuit generates the second repair information according to a test result of the built-in self-test. The controller reconfigures the main memory and a spare memory or an embedded redundant memory according to the second repair information.

### REFERENCE TO RELATED APPLICATIONS

This non-provisional application claims priority under 35 U.S.C. § 119(a) on Taiwan Patent Application No. 108144076 filed on Dec. 3, 2019, and the entire contents of which are incorporated herein by reference.

### TECHNICAL FIELD

The present disclosure relates to a memory repair technology, more particularly, to a memory repair circuit, a memory repair method and a memory module having the memory repair circuit that are capable of cumulative repairs.

### BACKGROUND

Memory module is an essential component of various computing devices nowadays and allows a processing unit to access data in the memory module; herein the memory module can be volatile or non-volatile, the type of the memory module is not limited thereto. The memory module commonly includes a main memory and a redundant memory, wherein when faults are found in some row or some column of memory cells in the main memory, the redundant memory provides a row or column of memory cells to replace the row or column containing the defected memory cells. In short, the redundant memory is used for repairing the row or column containing defected memory cells.

Current memory repair methods can be sorted into either soft repair or hard repair. The soft repair method executes built-in self-test (BIST) when the electronic device is boot up or powered on, such that the memory is checked by the built-in self-test for defected memory cells at each boot up. The addresses of all of the defected memory cells are stored respectively during testing and are mapped to the addresses of non-defected memory cells in the redundant memory in the progress of address mapping. Although the soft repair method is able to perform multi-time repairs to defected memory cells in the memory module and has a lower design overhead, long repair setup time is one of the technical issues faced by the soft repair method.

The hard repair method uses fuse in combination with programming to disconnect or blow the fuse corresponding to the row or column that contains defected memory cells and replaces the row or column containing the defected memory cells with a row or column of memory cells in the redundant memory, wherein the fuse disconnection is done by, for example, laser or high voltage. Most of the current memory modules adopt the hard repair method because of its shorter repair setup time. However, some technical issues of the hard repair method include one-time repair only, to the defected memory cells, and the need for additional fuses and hardware.

### SUMMARY

To solve the aforementioned issues, an objective of the present disclosure is to provide a repair circuit and a repair method for memory and a memory module using the repair circuit that not only overcome the deficiencies of the conventional hard repair and soft repair methods but at the same time obtain at least parts of their advantages.

An objective of the present disclosure is to provide a memory repair circuit that includes a non-volatile storage unit, a volatile storage unit, a controller, a self-test circuit, and a repair information generating circuit. The non-volatile storage unit stores a first repair information. The volatile storage unit is electrically connected to the non-volatile storage unit and functions as a data transmission bridge between the non-volatile storage unit and the repair information generating circuit. The controller is electrically connected to the volatile storage unit, the non-volatile storage unit and the repair information generating circuit and controls reading and burning of the first repair information and a second repair information. The self-test circuit is electrically connected to a main memory and the repair information generating circuit and, after the main memory and a spare memory or an embedded redundant memory are configured according to the first repair information, performs a built-in self-test on the main memory. The repair information generating circuit is electrically connected to the main memory and, where there be the spare memory, the spare memory, and generates the second repair information according to a test result of the built-in self-test. The controller further configures the main memory and the spare memory or the embedded redundant memory according to the second repair information.

Optionally, the first repair information records a former mapping between an address of at least one first memory cell in the main memory and an address of at least one second memory cell in the spare memory or the embedded redundant memory. The second repair information records a current mapping between an address of at least one first memory cell in the main memory and an address of at least one second memory cell in the spare memory or the embedded redundant memory.

Optionally, the controller further controls the non-volatile storage unit to update the first repair information to the second repair information according to a user selection or an operating condition.

Optionally, the self-test circuit performs the built-in self-test to the main memory according to a user selection or an operating condition.

Optionally, the repair information generating circuit generates the second repair information when the test result indicates the main memory failed the built-in self-test.

Another objective of the present disclosure is to provide a memory module that includes the aforementioned memory repair circuit, a main memory, and a spare memory or an embedded redundant memory.

Another objective of the present disclosure is to provide a memory repair method that includes the steps of: at boot up, utilizing a volatile storage unit to read a first repair information stored in a non-volatile storage unit; configuring a main memory and a spare memory or an embedded redundant memory according to the first repair information; after the main memory and the spare memory or the embedded redundant memory are configured according to the first repair information, performing a built-in self-test on the main memory; generating a second repair information according to a test result of the built-in self-test; and reconfiguring the main memory and the spare memory or the embedded redundant memory according to the second repair information.

According to the above memory repair method, the first repair information records a former mapping between an address of at least one first memory cell in the main memory and an address of at least one second memory cell in the spare memory or the embedded redundant memory. The second repair information records a current mapping between an address of at least one first memory cell in the main memory and an address of at least one second memory cell in the spare memory or the embedded redundant memory.

According to the above memory repair method, the memory repair method further includes the steps of controlling the non-volatile storage unit to update the first repair information to the second repair information according to a user selection or an operating condition; and performing the built-in self-test on the main memory according to the user selection or the operating condition.

According to the above memory repair method, the second repair information is generated when the test result indicates the main memory failed the built-in self-test.

In short, the memory module, the memory repair circuit and the memory repair method disclosed by the present disclosure have advantages such as the short repair setup time from the hard repair method and the multi-time repair ability from the soft repair method.

### BRIEF DESCRIPTION OF THE DRAWINGS

The structure as well as preferred modes of use, further objectives, and advantages of this present disclosure will be best understood by referring to the following detailed description of some illustrative embodiments in conjunction with the accompanying drawings, in which:

FIG. 1A is a block diagram of a memory module according to an embodiment of the present disclosure.

FIG. 1B is a block diagram of a memory module according to another embodiment of the present disclosure.

FIG. 2 is a flow chart of a memory repair method according an embodiment of the present disclosure.

### DETAILED DESCRIPTION OF THE PREFERRED EMBODIMENTS

The present disclosure provides a memory repair circuit, a memory repair method and a memory module using the memory repair circuit that have at least some advantages of both the hard repair method and the soft repair method and are capable of cumulative repairs. The memory module is, for example but not limited to, an SDRAM module. In the application of electronic devices with longer service life, the memory repair circuit, the memory repair method and the memory module are able to repair newly defected memory cells and ensure the electronic device can operate normally.

The memory repair circuit and the memory repair method of the present disclosure take actions to repair defects in a main memory based on a test result of a built-in self-test performed on the main memory. More specifically, the memory repair circuit and the memory repair method use a non-volatile storage unit to store a first repair information and a volatile storage unit to temporarily store a second repair information, wherein the first repair information records a former mapping between the addresses of first memory cells in the main memory and the addresses of second memory cells in a spare memory, and the second repair information records a current mapping between the addresses of first memory cells in the main memory and the addresses of second memory cells in the spare memory. The first memory cells in the main memory are, for example but not limited to, defected memory cells in the main memory, and the second memory cells in the spare memory are non-defected memory cells. The former mapping refers to the mapping of addresses before the built-in self-test is conducted at this boot up, and the current mapping refers to the mapping of addresses after the built-in self-test has been conducted at this boot up. The mapping of addresses is the relationship between the addresses of the corresponding memory cells in the main memory and the spare memory.

At boot up/power on, the first repair information stored in the non-volatile storage unit is read by and stored temporarily in the volatile storage unit and is used to configure the main memory and the spare memory. When the built-in self-test is performed on the main memory and the test result indicates that there are defected memory cells newly detected in the main memory, the memory repair circuit and the memory repair method configure the main memory and the spare memory to generate the second repair information and store the second repair information in the volatile storage unit temporarily to update the first repair information temporarily stored in the volatile storage. Then, according to operating condition/status and scenario, the first repair information stored in the non-volatile storage unit can be selectively updated to the second repair information. Simply put, the memory repair circuit and the memory repair method provide a cumulative repair function. Further, the spare memory and the main memory are memories that are independent of each other, or the spare memory is an embedded redundant memory that is embedded in the main memory.

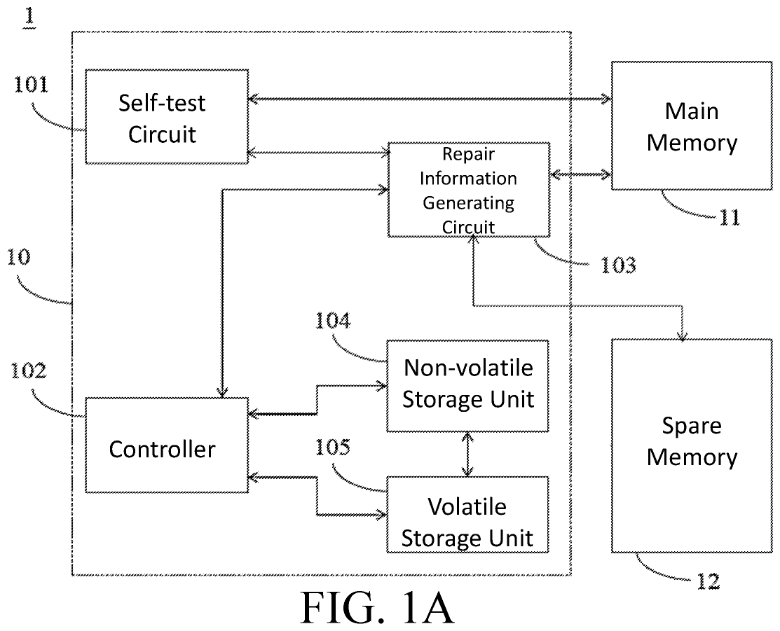

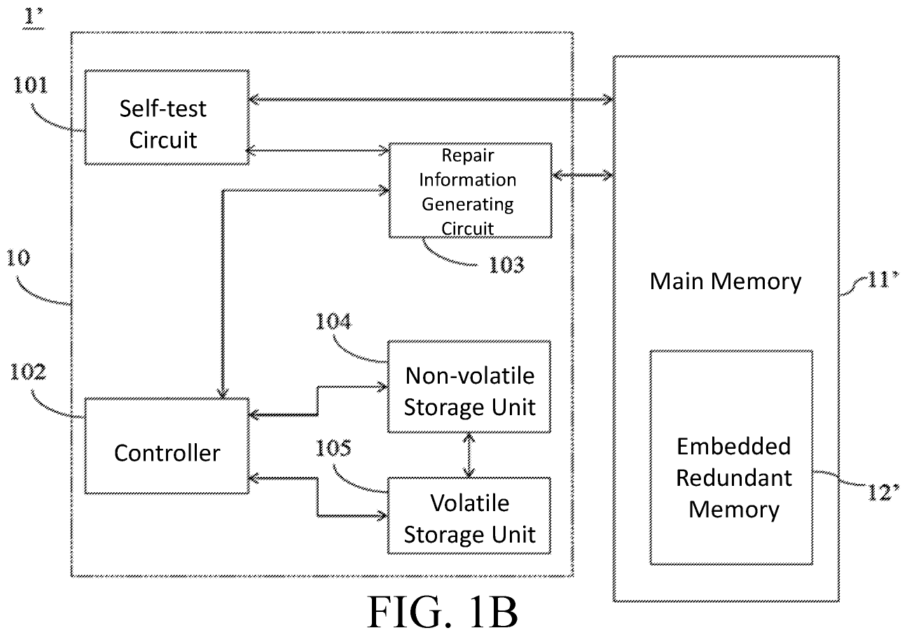

First, referring to FIG. 1A, which is a block diagram of a memory module according to an embodiment of the present disclosure, the memory module 1 includes a memory repair circuit 10, a main memory 11 and a spare memory 12, wherein the memory repair circuit 10 is electrically connected to the main memory 11 and the spare memory 12. At boot up/power on, the memory repair circuit 10 reads a first repair information stored in the memory circuit 10 and configures the main memory 11 and the spare memory 12 according to the first repair information such that the first memory cells, namely the defected memory cells, in the main memory are mapped to the second memory cells in the spare memory as recorded in the first repair information.

Next, if the built-in self-test is conducted and the test result indicates that there are new defected memory cells found in the main memory, implying that defected memory cells still exist in the main memory even after the main memory 11 has been repaired according to the first repair information, the memory repair circuit 10 generates the second repair information according to the test result. The second repair information is temporarily stored by the memory repair circuit 10 and the memory repair circuit 10 then configures the main memory 11 and the spare memory 12 according to the second repair information so that the new defected memory cells (first memory cells) in the main memory 11 are mapped to the (second) memory cells in the spare memory 12. Subsequently, according to a user selection or an operating condition, the memory repair circuit 10 updates the first repair information to the second repair information. In other words, the memory repair circuit 10 is capable of cumulative repairs and thus has advantages of both the hard repair method and the soft repair method such as short repair setup time, multi-time repair ability, and lower design overhead.

Now, the memory repair circuit 10 will be further described in detail. The memory repair circuit 10 includes a self-test circuit 101, a controller 102, a repair information generating circuit 103, a non-volatile storage unit 104, and a volatile storage unit 105. The self-test circuit 101 is electrically connected to the main memory 11 and the repair information generating circuit 103. The repair information generating circuit 103 is electrically connected to the main memory 11, the controller 102, and the spare memory 12. The non-volatile storage unit 104 is electrically connected to the volatile storage unit 105 and the controller 102, and the volatile storage unit 105 is electrically connected to the controller 102.

During the boot up/power on, the controller 102 controls the volatile storage unit 105 to read the first repair information stored in the non-volatile storage unit 104, wherein the first repair information records the former mapping between the addresses of defected/first memory cells in the main memory 11 and the addresses of second memory cells in the spare memory 12. The former mapping refers to the mapping of addresses before conducting the built-in self-test in this boot up/power on. Then, the controller 102 configures the main memory 11 and the spare memory 12 according to the first repair information temporarily stored in the volatile storage unit 105 so as to map the address of the defected/first memory cell in the main memory 11 to the address of the second memory cell in the spare memory 12 and thereby repairing the defected memory cell of the main memory 11.

Next, according to the user selection or operating condition, the self-test circuit 101 selectively performs the built-in self-test on the main memory 11 to check whether the main memory 11 has new defected memory cells. If the built-in self-test is selected not to be performed on the main memory 11, the controller 102 controls the memory module 1 to operate in normal mode. If performing the built-in self-test on the main memory 11 is chosen and the test result indicates that no new defected memory cell was found in the main memory 11, the controller 102 controls the memory module 1 to operate in normal mode.

If the built-in self-test is performed on the main memory 11 and the test result indicates new defected memory cells were found in the main memory 11, the controller 102 controls the repair information generating circuit 103 to generate the second repair information according to the test result. The controller 102 stores the second repair information in the volatile storage unit 105 first before reconfiguring the main memory 11 and the spare memory 12 according to the second repair information temporarily stored in the volatile storage unit 105 to map the addresses of the defected/first memory cells in the main memory 11 to the addresses of the second memory cells in the spare memory 12 so that the new defected memory cells (first memory cells) in the main memory can be repaired as well (i.e. the controller 102 controls the memory module 1 to operate in repairing mode). Afterwards, the controller 102 controls the memory module 1 to operate in normal mode. Moreover, according to the user selection or the operating condition, the controller 102 can control the non-volatile storage unit 104 to update the first repair information stored in the non-volatile storage unit 104 to the second repair information by storing the second repair information to replace the first repair information. To sum up, the controller 102 is used to control the reading and burning/writing of the first repair information and the second repair information, and the volatile storage unit 105 functions as a data transmission bridge between the non-volatile storage unit 104 and the repair information generating circuit 103.

FIG. 1B is a block diagram of a memory module according to another embodiment of the present disclosure. Referring to FIG. 1B, the memory module 1′ includes an embedded redundant memory 12′ in the main memory 11′ rather than having the spare memory 12 like the memory module 1 of FIG. 1A, and the embedded redundant memory 12′ is a redundant memory with a plurality of redundant rows or a plurality of redundant columns depending on the condition/situation. Furthermore, because the memory module 1′ does not have the spare memory 12, the repair information generating circuit 103 is only electrically connected to the main memory 11′, the controller 102 and the self-test circuit 101. The embedded redundant memory 12′ functions the same as the spare memory 12, which is to replace the defected memory cell (first memory cell) in the main memory 11′ so as to repair the defected memory cell (first memory cell) in the main memory 11′ and therefore the details of the memory module 1′ of FIG. 1B is not further described herein.

From the above description, it is clear that the memory module 1, 1′ and the memory repair circuit 10 integrated the non-volatile storage unit 104 and the volatile storage unit 105 to accomplish the cumulative repair function, and in turn overcame the technical issue of the conventional soft repair method that the repair setup time after conducting the built-in self-test at each boot up being too long and the technical issue of the conventional hard repair method that extra hardware equipment being required to program the fuse. The memory module 1, 1′ and the memory repair circuit 10 of the present disclosure further have advantages of both the hard repair method and the soft repair method such as short repair setup time, multi-time repair ability and low design overhead. Moreover, the memory repair circuit 10 of the present disclosure is capable of supporting the memory module 1 having the architecture of an independent spare memory 12 as well as the memory module 1′ having the architecture of an embedded redundant memory 12′ with a plurality of redundant rows or columns. The memory repair circuit 10 is also able to, according to the user selection or operating condition, provide flexible control interface and programmable operation process for determining whether to conduct the built-in self-test and/or to update the first repair information stored in the non-volatile storage unit 104.

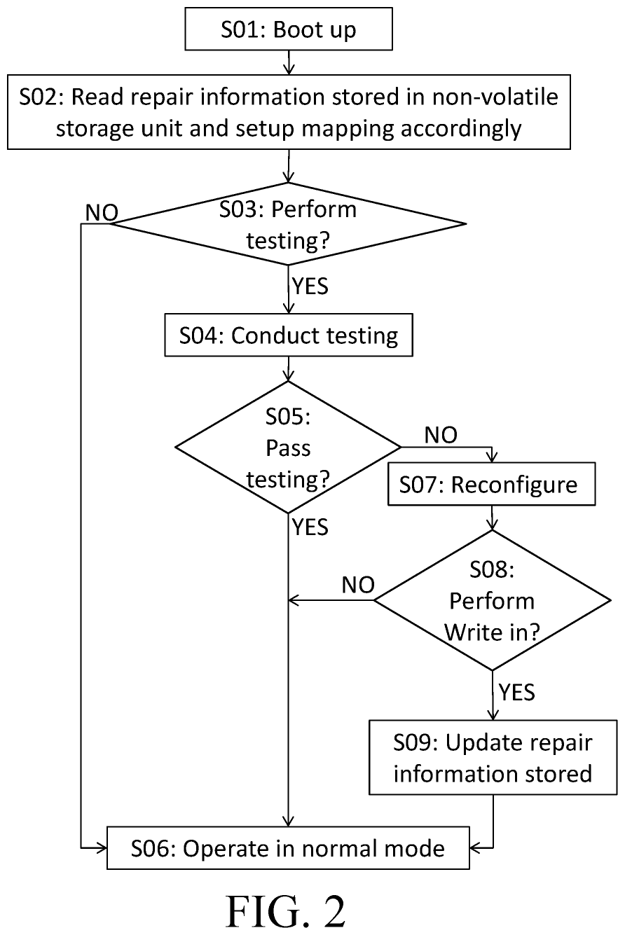

FIG. 2 is a flow chart of a memory repair method according to an embodiment of the present disclosure. Referring to FIG. 2, the memory repair method provides a cumulative repair function and is executable by a memory repair circuit like the memory repair circuit 10 of FIG. 1A and FIG. 1B, but is not limited thereto. First, in step S01, an electronic device having a memory module boots up/powers on. In step S02, a volatile storage unit of a memory repair circuit reads a first repair information stored in a non-volatile storage unit of the memory repair circuit and a controller of the memory repair circuit configures a main memory and a spare memory or an embedded redundant memory according to the first repair information so as to map an address of at least one defected/first memory cell in the main memory to an address of at least one second memory cell in the spare memory or the embedded redundant memory.

Then, the controller of the memory repair circuit determines whether to conduct a built-in self-test according to an operating condition or a user selection in step S03. If the built-in self-test is not conducted, proceed to step S06, and if the built-in self-test is conducted, proceed to step S04. Step S04 is a self-test circuit of the memory repair circuit performing the built-in self-test on the main memory and step S05 is the self-test circuit of the memory repair circuit judging whether the main memory passed the test according to a test result. If the judgement is that the test result is a pass, it implies that no new defected memory cell was found in the main memory and step S06 is executed, and if the judgement is that the test result is a fail, it implies that new defected memory cells were found in the main memory and that the main memory failed the built-in self-test, and step S07 is executed. In step S06, the controller of the memory repair circuit controls the memory module to operate in normal mode.

In step S07, a repair information generating circuit of the memory repair circuit generates a second repair information according to the test result and the second repair information is temporarily stored in the volatile storage unit of the memory repair circuit before the controller of the memory repair circuit reconfigures the main memory and the spare memory or the embedded redundant memory according to the second repair information, which maps the addresses of the new and old defected memory cells (first memory cells) in the main memory to the addresses of the (second) memory cells in the spare memory or the embedded redundant memory. Subsequently in step S08, the controller of the memory repair circuit decides whether to burn or write the second repair information into the non-volatile storage unit according to the user selection or the operating condition so as to update the first repair information stored in the non-volatile storage unit to the second repair information. If the second repair information is to be burnt/written into the non-volatile storage unit, step S09 is processed, and if the second repair information is not to be burnt/written into the non-volatile storage unit, step S06 is processed. In step S09, the non-volatile storage unit of the memory repair circuit stores the second repair information and updates the first repair information stored in the non-volatile storage unit to the second repair information.

It is to be noted that the memory repair method of FIG. 2 is merely an embodiment of the present disclosure and the present disclosure is not limited thereby. For example, an additional built-in self-test can be conducted between step S07 and step S08 for checking whether the main memory is successfully repaired by the second repair information. Further, step S03 and/or step S08 can be removed selectively such that step S04 and/or step S09 become mandatory steps to be executed in the memory repair method. In addition, the aforementioned operating condition can be periodic inspection status or maintenance status and the present disclosure is not limited thereby.

In view of above, the technical benefits of the memory repair circuit, the memory repair method and the memory module having the memory repair circuit as described by the embodiments of the present disclosure, in comparison to the conventional technology, are described below.

In convention technology, the soft repair method has the technical issue of long repair setup time and the hard repair method has the technical issue of requiring extra fuse and hardware. However, the memory module, the memory repair circuit and the memory repair method of the present disclosure integrate the non-volatile storage unit and the volatile storage unit to solve the technical issue of the soft repair method where the repair setup time after conducting the built-in self-test at each boot up is too long and the technical issue of the hard repair method where extra hardware equipment is needed to program the fuse. At the same time, the memory module, the memory repair circuit, and the memory repair method of the present disclosure further includes advantages such as short repair setup time from the hard repair method and multi-time repair ability and low design overhead from the soft repair method. Furthermore, the memory module, the memory repair circuit, and the memory repair method of the present disclosure can be implemented in all sorts of electronic devices that have memory and therefore have industrial applicability and vast market and economic benefits.

The above disclosure is only the preferred embodiment of the present disclosure, and not used for limiting the scope of the present disclosure. All equivalent variations and modifications on the basis of shapes, structures, features and spirits described in claims of the present disclosure should be included in the claims of the present disclosure.

1. A memory repair circuit comprising:
a non-volatile storage unit for storing a first repair information;
a repair information generating circuit for generating a second repair information;
a volatile storage unit electrically connected to the non-volatile storage unit for functioning as a data transmission bridge between the non-volatile storage unit and the repair information generating circuit;
a controller electrically connected to the non-volatile storage unit, the volatile storage unit, and the repair information generating circuit for controlling reading and burning of the first repair information and the second repair information; and
a self-test circuit electrically connected to a main memory for performing a built-in self-test to the main memory after the main memory and a spare memory or an embedded redundant memory are configured according to the first repair information;
wherein the repair information generating circuit is electrically connected to the main memory and generates the second repair information according to a test result of the built-in self-test, and when the spare memory exists, the repair information generating circuit is further electrically connected to the spare memory;
wherein the controller further reconfigures the main memory and the spare memory or the embedded redundant memory according to the second repair information.

2. The memory repair circuit of claim 1, wherein the second repair information records a current mapping between an address of at least one first memory cell in the main memory and an address of at least one second memory cell in the spare memory or the embedded redundant memory.

3. The memory repair circuit of claim 2, wherein the first repair information records a former mapping between an address of at least one first memory cell in the main memory and an address of at least one second memory cell in the spare memory or the embedded redundant memory.

4. The memory repair circuit of claim 1, wherein the controller further controls the non-volatile storage unit to update the first repair information to the second repair information according to a user selection or an operating condition.

5. The memory repair circuit of claim 1, wherein the self-test circuit performs the built-in self-test according to a user selection or an operating condition.

6. The memory repair circuit of claim 1, wherein the repair information generating circuit generates the second repair information when the test result indicates the main memory failed the built-in self-test.

7. A memory module comprising:
a main memory;
a spare memory or an embedded redundant memory; and
a memory repair circuit as described in claim 1.

8. The memory module of claim 7, wherein the second repair information records a current mapping between an address of at least one first memory cell in the main memory and an address of at least one second memory cell in the spare memory or the embedded redundant memory.

9. The memory module of claim 8, wherein the first repair information records a former mapping between an address of at least one first memory cell in the main memory and an address of at least one second memory cell in the spare memory or the embedded redundant memory.

10. The memory module of claim 7, wherein the controller further controls the non-volatile storage unit to update the first repair information to the second repair information according to a user selection or an operating condition.

11. The memory module of claim 7, wherein the self-test circuit performs the built-in self-test according to a user selection or an operating condition.

12. The memory module of claim 7, wherein the repair information generating circuit generates the second repair information when the test result indicates the main memory failed the built-in self-test.

13. A memory repair method comprising:
utilizing a volatile storage unit to read a first repair information stored in a non-volatile storage unit at boot up;
configuring a main memory and a spare memory or an embedded redundant memory according to the first repair information;
performing a built-in self-test on the main memory after the main memory and the spare memory or the embedded redundant memory are configured according to the first repair information;
generating a second repair information according to a test result of the built-in self-test; and
reconfiguring the main memory and the spare memory or the embedded redundant memory according to the second repair information.

14. The memory repair method of claim 13, wherein the second repair information records a current mapping between an address of at least one first memory cell in the main memory and an address of at least one second memory cell in the spare memory or the embedded redundant memory.

15. The memory repair method of claim 14, wherein the first repair information records a former mapping between an address of at least one first memory cell in the main memory and an address of at least one second memory cell in the spare memory or the embedded redundant memory.

16. The memory repair method of claim 13, further comprising:
controlling the non-volatile storage unit to update the first repair information to the second repair information according to a user selection or an operating condition.

17. The memory repair method of claim 13, further comprising:
performing the built-in self-test on the main memory according to an user selection or an operating condition.

18. The memory repair method of claim 13, wherein the second repair information is generated when the test result indicates the main memory failed the built-in self-test.
